(19) United States
(12) Patent Application Publication
(10) Pub. No.: US 2026/0312568 A1
(43) Pub. Date: Oct. 8, 2026

(54) PHASE ADJUSTMENT CIRCUIT

(71) Applicant: NTT, Inc., Tokyo (JP)

(72) Inventors: Tsutomu Takeya, Tokyo (JP); Munehiko Nagatani, Tokyo (JP); Hiroyuki Takahashi, Tokyo (JP); Hitoshi Wakita, Tokyo (JP); Teruo Jo, Tokyo (JP)

(21) Appl. No.: 19/139,012

(22) PCT Filed: Dec. 15, 2022
(86) PCT No.: PCT/JP2022/046188

§ 371 Date: Jun. 13, 2025

(51) Int. Cl. H03H 11/16

(52) U.S. Cl. CPC H03H 11/16

(57) ABSTRACT

A phase adjustment circuit includes a clock generation circuit for generating a sine wave shaped clock signal, an amplifier circuit for amplifying the clock signal, a transmission line in which an input end is connected to an output terminal of the amplifier circuit, a load circuit which is connected to a termination of the transmission line and whose impedance can be adjusted from the outside, and an amplifier circuit in which a signal obtained by adding an output signal of the amplifier circuit and a return signal from the transmission line at an output terminal of the amplifier circuit is input.

### CROSS-REFERENCE TO RELATED APPLICATIONS

This application is a national phase entry of PCT Application No. PCT/JP2022/046188, filed on Dec. 15, 2022, which application is hereby incorporated herein by reference.

### TECHNICAL FIELD

The present invention relates to a phase adjustment circuit of a sine wave.

### BACKGROUND

In the present day, the sine wave plays an important role. In communication, the sine wave may be used for generating a carrier wave, or the sine wave may be used as a clock. In the communication, the clock is used not only as the carrier wave, but also as a timing reference for judging data.

When the clock is used as the timing reference for such data judgment, it is necessary to adjust a phase of the clock and perform the data judgment at appropriate timing. As a method for performing the data judgment at the appropriate timing, there is clock data recovery. As a means for realizing the clock data recovery, a configuration using a phase comparator and a phase adjustment circuit is known. In this configuration, the phases are compared by some means, and a desired phase is generated on the basis of a comparison result.

Conventionally, as the phase adjustment circuit, a configuration disclosed in NPL 1 has been known. The configuration of the conventional phase adjustment circuit is shown in FIG. 28. In the configuration in FIG. 28, by adding a sine wave sinωt as a reference and a sine wave cosωt having a fixed phase difference of π/2 with respect to the sine wave sinωt by an adder 203, an arbitrary intermediate phase waveform is generated. The sine waves sinωt and cosωt are multiplied by constants A and B by multipliers 201 and 202, respectively. The following equation is established from trigonometric function combined equation.

$$\begin{matrix}[ Math . 1 ] & \\ A sin ω t + B cos ω t = \sqrt{{A}^{2} + {B}^{2}} sin ( ω t + α ) & ( 1 )\end{matrix}$$

α in Equation (1) is as follows.

$$\begin{matrix}[ Math . 2 ] & \\ cos α = \frac{A}{\sqrt{{A}^{2} + {B}^{2}}} , sin α = \frac{B}{\sqrt{{A}^{2} + {B}^{2}}} & ( 2 )\end{matrix}$$

In the configuration in FIG. 28, the sine waves sinωt and cosωt are generated by using a Quadrature-VCO (Voltage Controlled Oscillator) 200. However, since the Quadrature-VCO 200 has a lower oscillation frequency due to its structure, there is a problem that it is difficult to use in a marginal region of a device. In addition, although a method of using a 90-degree hybrid has been known as a method of producing the sine wave having the fixed phase difference of π/2 from the sine wave, there is a problem that it operates only at a specific frequency when using the 90-degree hybrid.

### CITATION LIST

### Non Patent Literature

[NPL 1] Arun Goyal, et al., “A High-Resolution Digital Phase Interpolator Based CDR with a Half-Rate HybridPhase Detector”, 2019 IEEE International Symposium on Circuits and Systems (ISCAS), May 2019

### SUMMARY

The present invention is made to solve above-described problems, and an object thereof is to provide a phase adjustment circuit that can be used in a wide frequency range.

### Solution to Problem

A phase adjustment circuit of the present invention is characterized in that it includes a clock generation circuit configured to generate a sine wave shaped clock signal, an amplifier circuit configured to amplify the clock signal output from the clock generation circuit, a transmission line in which an input end is connected to an output terminal of the amplifier circuit, a load circuit which is connected to a termination of the transmission line and whose impedance can be adjusted from the outside, and an output circuit in which a signal obtained by adding an output signal of the amplifier circuit and a return signal from the transmission line at the output terminal of the amplifier circuit is input.

### Advantageous Effects of Invention

According to the present invention, by providing the clock generation circuit, the amplifier circuit, the transmission line, the load circuit, and the output circuit, it is not necessary to use the conventional Quadrature-VCO as the clock generation circuit which is a base of the sine wave signal, an LC-VCO including an LC oscillator which is generally used as the clock generation circuit can be used, the clock having the intermediate phases can be generated, and operation with higher frequency can be realized. In addition, the present invention can be used in a wide frequency range, as compared with the configuration in which the 90-degree hybrid is used as the clock generation circuit.

### BRIEF DESCRIPTION OF THE DRAWINGS

FIG. 1 is a block diagram showing a configuration of a phase adjustment circuit according to a first example of the present invention.

FIG. 2 is a diagram showing simulation results of the phase adjustment circuit according to the first example of the present invention.

FIG. 3 is a block diagram showing a configuration of a phase adjustment circuit according to a second example of the present invention.

FIG. 4 is a circuit diagram showing a configuration of an amplifier circuit according to the second example of the present invention.

FIG. 5 is a block diagram showing a configuration of a phase adjustment circuit according to a third example of the present invention.

FIG. 6 is a circuit diagram showing a configuration of a mixer according to the third example of the present invention.

FIG. 7 is a block diagram showing a configuration of a phase adjustment circuit according to a fourth example of the present invention.

FIG. 8 is a block diagram showing a configuration of a phase adjustment circuit according to a fifth example of the present invention.

FIG. 9 is a block diagram showing a configuration of a phase adjustment circuit according to a sixth example of the present invention.

FIG. 10 is a circuit diagram showing a configuration of a signal quality evaluation circuit according to the sixth example of the present invention.

FIG. 11 is a circuit diagram showing a configuration of a load circuit according to a seventh example of the present invention.

FIG. 12 is a circuit diagram showing another configuration of a load circuit according to the seventh example of the present invention.

FIG. 13 is a circuit diagram showing another configuration of a load circuit according to the seventh example of the present invention.

FIG. 14 is a circuit diagram showing another configuration of a load circuit according to the seventh example of the present invention.

FIG. 15 is a circuit diagram showing another configuration of a load circuit according to the seventh example of the present invention.

FIG. 16 is a circuit diagram showing another configuration of a load circuit according to the seventh example of the present invention.

FIG. 17 is a circuit diagram showing another configuration of a load circuit according to the seventh example of the present invention.

FIG. 18 is a circuit diagram showing another configuration of a load circuit according to the seventh example of the present invention.

FIG. 19 is a circuit diagram showing another configuration of a load circuit according to the seventh example of the present invention.

FIG. 20 is a circuit diagram showing another configuration of a load circuit according to the seventh example of the present invention.

FIG. 21 is a circuit diagram showing another configuration of a load circuit according to the seventh example of the present invention.

FIG. 22 is a circuit diagram showing another configuration of a load circuit according to the seventh example of the present invention.

FIG. 23 is a circuit diagram showing another configuration of a load circuit according to the seventh example of the present invention.

FIG. 24 is a circuit diagram showing another configuration of a load circuit according to the seventh example of the present invention.

FIG. 25 is a cross-sectional view showing a configuration of a transmission line according to an eighth example of the present invention.

FIG. 26 is a cross-sectional view showing another configuration of a transmission line according to the eighth example of the present invention.

FIG. 27 is a cross-sectional view showing another configuration of a transmission line according to the eighth example of the present invention.

FIG. 28 is a block diagram showing a configuration of a conventional phase adjustment circuit.

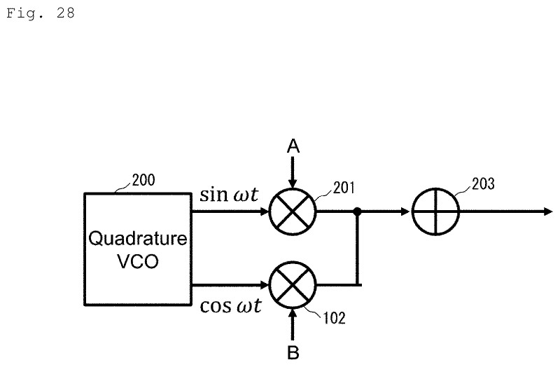

### DETAILED DESCRIPTION OF ILLUSTRATIVE EMBODIMENTS

### Principles of the Invention

In the present invention, a function of adjusting a sine wave to an arbitrary phase is realized by a circuit configuration in which a transmission line having an impedance variable load is provided to a clock buffer.

### First Example

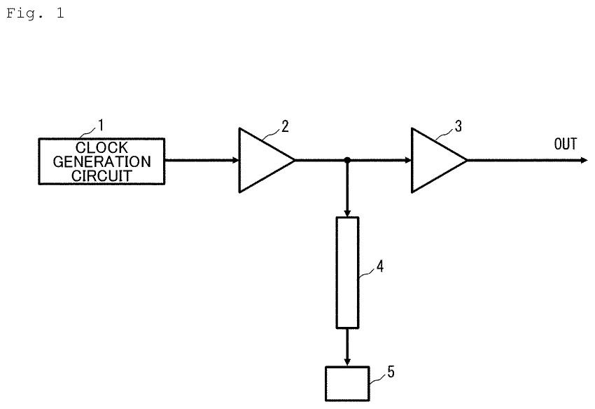

Hereinafter, examples of the present invention will be described with reference to the drawings. FIG. 1 is a block diagram showing a configuration of a phase adjustment circuit according to a first example of the present invention. The phase adjustment circuit includes a clock generation circuit 1 for generating a sine wave shaped clock signal, an amplifier circuit 2 for amplifying the clock signal output from the clock generation circuit 1, an amplifier circuit 3 in which an input terminal is connected to an output terminal of the amplifier circuit 2, a transmission line 4 in which an input end is connected to the output terminal of the amplifier circuit 2, and a load circuit 5 which is connected to a termination of the transmission line 4 and whose impedance can be adjusted from the outside.

In the configuration shown in FIG. 1, the sine wave shaped clock signal output from the clock generation circuit 1 passes through the amplifier circuit 2 and is input to the amplifier circuit 3 and the transmission line 4. Since the impedance of the transmission line 4 is different from the impedance of the load circuit 5, the signal input to the transmission line 4 is reflected at the termination of the transmission line 4 and returned to the output of the amplifier circuit 2. Therefore, the signal output from the amplifier circuit 2 and the signal delayed by a round trip of the transmission line 4 are added at the output terminal of the amplifier circuit 2.

As the amplifier circuits 2 and 3, a buffer circuit having an amplification factor of 1 may be used, an amplifier circuit having an amplification factor higher than 1 may be used, or an amplifier circuit having an amplification factor higher than 0 and lower than 1 may be used. In the present example, the amplifier circuit 3 is used as an output circuit in which a signal obtained by adding an output signal of the amplifier circuit 2 and a return signal from the transmission line 4 at the output terminal of the amplifier circuit 2 is input, but the output circuit may not be an amplifier circuit as described later, a circuit in which a mixer and a filter are combined may be used.

Operation of the phase adjustment circuit will be described using mathematical equations. When the signal input from the amplifier circuit 2 to the transmission line 4 is set to Asinωt and the signal reflected and returned from the transmission line 4 is set to Bsin(ωt+φ), the output signal OUT of the amplifier circuit 3 finally becomes as the following equation.

$$\begin{matrix}[ Math . 3 ] & \\ OUT = A sin ω t + B sin ( ω t + φ ) = Im [ A {e}^{j ω t} + B {e}^{j ( ω t + φ )} ] = Im [ ( A + B {e}^{j φ} ) {e}^{j ω t} ] = Im [ r {e}^{j ρ} {e}^{j ω t} ] & ( 3 )\end{matrix}$$

In Equation (3), the amplification factor of the amplifier circuit 3 is set to 1. ejωt represents a reference sine wave. Since Bsin(ωt+φ) is the reflection wave returned from the transmission line 4, it is not amplified, and B<A is satisfied. The values of B and D depend on the impedance of the load circuit 5 and the length of the transmission line 4.

It can be seen from Equation (3) that the sine wave having the phase different by p from the reference phase can be generated by adding the sine wave having the reference frequency and the sine wave having the different phase by an arbitrary phase p from the sine wave having the reference phase. Since the amount of change in the output phase is obtained by calculating re^{jp}, when rearranging Equation (3), Equation (4) is obtained.

$$\begin{matrix}[ Math . 4 ] & \\ {re}^{j ρ} = A + B {e}^{j φ} = A + B cos ( φ ) + jB sin ( φ ) = B [ \frac{A}{B} + cos ( φ ) + j sin ( φ ) ] = B [ x + cos ( φ ) + j sin ( φ ) ] & ( 4 )\end{matrix}$$

Here, the phase angle ρ is given by Equation (5).

$$\begin{matrix}[ Math . 5 ] & \\ ρ = arg ( B [ x + cos ( φ ) + j sin ( φ ) ] ) = arg ( x + cos ( φ ) + j sin ( φ ) ) & ( 5 )\end{matrix}$$

Note that although influence of multiple reflection is ignored here, a possibility of generating the sine wave of the intermediate phase can be described by a similar discussion even when there is the multiple reflection. In the example in FIG. 1, a single-phase configuration is shown, but it can be realized by a circuit having a differential configuration.

Next, actual operation of the phase adjustment circuit will be described in more detail. The output impedance of the amplifier circuit 2 is set to r₀, the characteristic impedance of the transmission line 4 is set to Z₀, and the impedance of the load circuit 5 is set to Z_{T}. The impedance Zᵢₙ of the transmission line 4 and the load circuit 5 viewed from the input of the transmission line 4 is expressed by Equation (6).

$$\begin{matrix}[ Math . 6 ] & \\ {Z}_{i n} = {Z}_{0} \frac{{Z}_{T} + j {Z}_{0} tan BL}{{Z}_{0} + j {Z}_{T} tan BL} & ( 6 )\end{matrix}$$

B is a phase constant, and L is a length of the transmission line 4. Since B×L is determined by physical structure and a frequency of a signal, when attention is paid to a specific frequency, tanBL may be regarded as a constant. The impedance Zₒᵤₜ at the output terminal of the amplifier circuit 2 is a combined resistance of Zᵢₙ and r₀, and can be expressed by Equation (7).

$$\begin{matrix}[ Math . 7 ] & \\ {Z}_{o u t} = {r}_{0} {Z}_{0} \frac{{Z}_{T} + j {Z}_{0} tan BL}{{Z}_{0} ( {Z}_{T} + {r}_{0} ) + j ( {Z}_{0}^{2} + {Z}_{T} {r}_{0} ) tan BL} & ( 7 )\end{matrix}$$

Generally, the output voltage of the amplifier circuit is expressed by the product of the transconductance and the impedance of the output terminal. Therefore, when the transconductance of the amplifier circuit 2 is set to gma, the output voltage Vₒᵤₜ of the amplifier circuit 2 can be expressed by Equation (8).

$${V}_{o u t} = gma \times {Z}_{out} \qquad ( 8 )$$

It can be seen from the Equation (7) that argument of complex of the impedance Zₒᵤₜ changes by changing the impedance Z_{T} of the load circuit 5. That is, the phase of the output of the phase adjustment circuit can be adjusted by changing the impedance Z_{T}. However, it is necessary to eliminate a combination in which tanBL=0 is established among combinations of signal frequency and length of transmission line 4.

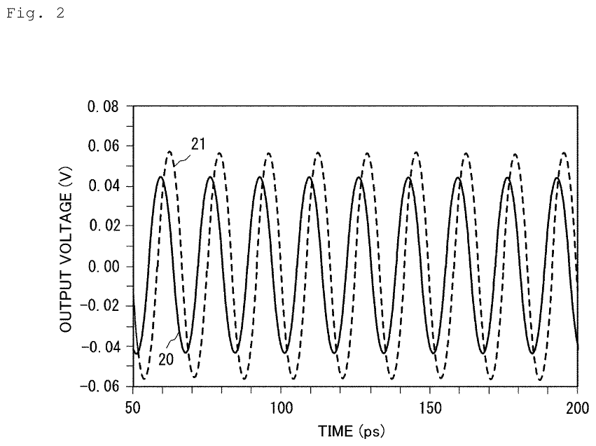

FIG. 2 shows a result of confirmation by circuit simulation that the phase of the sine wave changes by the phase adjustment circuit of the present example. 20 denotes the sine wave output from the clock generation circuit 1, and 21 denotes the sine wave whose phase is changed by the phase adjustment circuit of the present example. The frequency of the sine wave is 60 GHz. By changing the impedance Z_{T} of the load circuit 5, it is confirmed that the phase of the sine wave is changed by about 3 ps in time.

Note that as above-described mathematical analysis, the range of the impedance Z_{T} is not limited to a real number but may be a complex number. In addition, in order to prevent multiple reflection of the transmission line 4, the characteristic impedance Z₀ of the transmission line 4 and the output impedance r₀ of the amplifier circuit 2 may be matched.

### Second Example

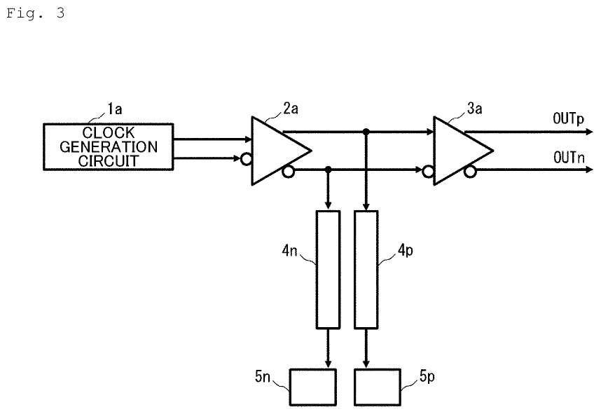

FIG. 3 is a block diagram showing a configuration of a phase adjustment circuit according to a second example of the present invention. The phase adjustment circuit of the present example includes a differential output type clock generation circuit 1a for generating a sine wave shaped differential clock signal, a differential input differential output type amplifier circuit 2a in which a non-inverting input terminal is connected to a non-inverting output terminal of the clock generation circuit 1a and an inverting input terminal is connected to an inverting output terminal of the clock generation circuit 1a, a differential input differential output type amplifier circuit 3a in which a non-inverting input terminal is connected to a non-inverting output terminal of the amplifier circuit 2a and an inverting input terminal is connected to an inverting output terminal of the amplifier circuit 2a, a transmission line 4p in which an input end is connected to the non-inverting output terminal of the amplifier circuit 2a, a transmission line 4n in which an input end is connected to the inverting output terminal of the amplifier circuit 2a, a load circuit 5p which is connected to an termination of the transmission line 4p and whose impedance can be adjusted from the outside, and a load circuit 5n which is connected to an termination of the transmission line 4n and whose impedance can be adjusted from the outside.

The transmission lines 4p and 4n have the same length L and the same characteristic impedance Z₀. The load circuits 5p and 5n are circuits having the same impedance Z_{T}. However, the impedance Z_{T} of the load circuits 5p and 5n may be adjusted to different values as described later.

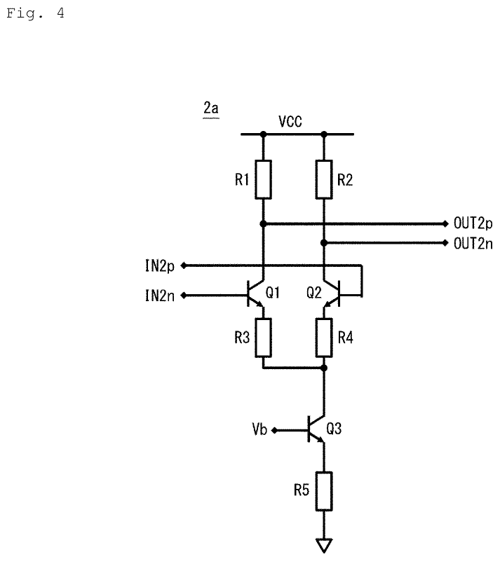

As the amplifier circuits 2a and 3a, a typical differential amplifier circuit shown in FIG. 4 can be used.

The amplifier circuit 2a is configured by an NPN bipolar transistor Q1 in which a clock signal IN2n on a negative phase side output from the clock generation circuit 1a is input to a base (inverting input terminal of the amplifier circuit 2a) and an output signal OUT2p on a positive phase side is output from a collector (non-inverting output terminal of the amplifier circuit 2a), an NPN bipolar transistor Q2 in which a clock signal IN2p on the positive phase side output from the clock generation circuit 1a is input to a base (non-inverting input terminal of the amplifier circuit 2a) and an output signal OUT2n on the negative phase side is output from a collector (inverting output terminal of the amplifier circuit 2a), a NPN bipolar transistor Q3 in which a bias voltage Vb is applied to a base, a resistor R1 in which one end is connected to a power supply voltage VCC and the other end is connected to the collector of the transistor Q1, a resistor R2 in which one end is connected to the power supply voltage VCC and the other end is connected to the collector of the transistor Q2, a resistor R3 in which one end is connected to an emitter of the transistor Q1 and the other end is connected to a collector of the transistor Q3, a resistor R4 in which one end is connected to an emitter of the transistor Q2 and the other end is connected to the collector of the transistor Q3, and a resistor R5 in which one end is connected to an emitter of the transistor Q3 and the other end is connected to ground.

The configuration of the amplifier circuit 3a is the same as that of the amplifier circuit 2a. Similarly to the first example, the amplification factors of the amplifier circuits 2a and 3a may be 1, higher than 1, or higher than 0 and lower than 1.

### Third Example

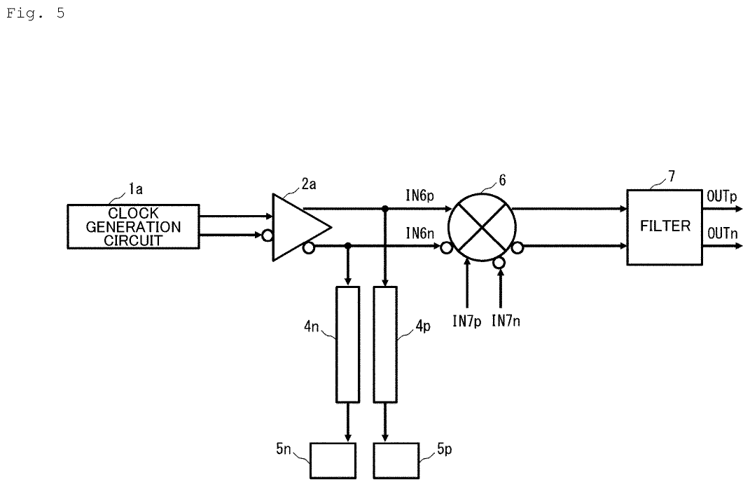

In the first and second examples, an arbitrary active circuit may be used instead of the amplifier circuit of the second stage. FIG. 5 is a block diagram showing a configuration of a phase adjustment circuit according to a third example of the present invention. The phase adjustment circuit of the present example includes a clock generation circuit 1a, an amplifier circuit 2a, transmission lines 4p and 4n, load circuits 5p and 5n, a differential input differential output type mixer 6 for mixing addition signals IN6p and IN6n of an output signals of the amplifier circuit 2a and return signals from the transmission lines 4p and 4n with carrier wave signals IN7p and IN7n input from the outside, and a differential input differential output type filter 7 for performing wave-filtering to output signals of the mixer 6 and passing differential signals OUTp and OUTn of a desired frequency.

The frequency of the addition signals IN6p and IN6n is set to f1, and the frequency of the carrier wave signals IN7p and IN7n is set to f2. When the addition signals IN6p and IN6n and the carrier wave signals IN7p and IN7n are mixed by the mixer 6, signals having a frequency f1±f2 of a sum and a difference are output from the mixer 6.

The filter 7 performs the wave-filtering to the output signals of the mixer 6 and passes signals of the frequency f1+f2, for example. By doing this, the addition signals IN6p and IN6n input to the mixer 6 can be converted into signals OUTp and OUTn of the higher frequency and output.

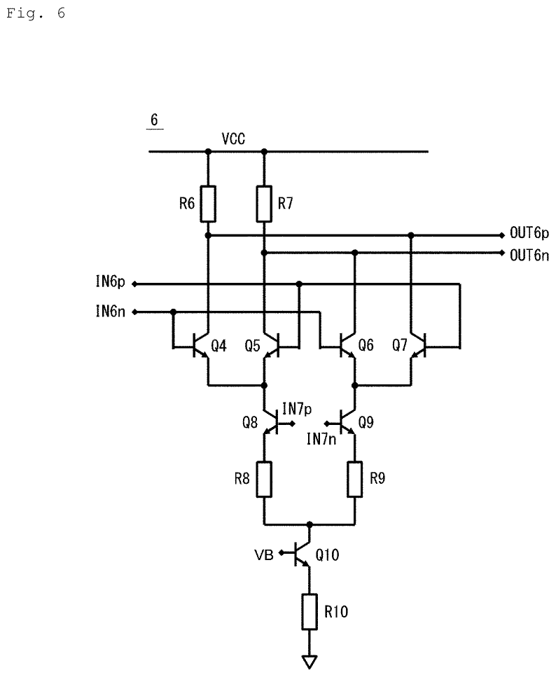

A Gilbert cell circuit shown in FIG. 6 can be used as the mixer 6 functioning as a multiplier. The mixer 6 is configured by an NPN bipolar transistor Q4 in which the addition signal IN6n on the negative phase side is input to a base and an output signal OUT6p on the positive phase side of the mixer 6 is output from a collector, an NPN bipolar transistor Q5 in which the addition signal IN6p on the positive phase side is input to a base and an output signal OUT6n on the negative phase side of the mixer 6 is output from a collector, an NPN bipolar transistor Q6 in which the addition signal IN6n is input to a base and the output signal OUT6n is output from a collector, an NPN bipolar transistor Q7 in which the addition signal IN6p is input to a base and the output signal OUT6p is output from a collector, an NPN bipolar transistor Q8 in which the carrier wave signal IN7p on the positive phase side is input to a base and a collector is connected emitters of the transistors Q4 and Q5, an NPN bipolar transistor Q9 in which the carrier wave signal IN7n on the negative phase side is input to a base and a collector is connected emitters of the transistors Q6 and Q7, an NPN bipolar transistor Q10 in which the bias voltage VB is applied to a base, a resistor R6 in which one end is connected to the power supply voltage VCC and the other end is connected to the collectors of the transistors Q4 and Q7, a resistor R7 in which one end is connected to the power supply voltage VCC and the other end is connected to the collectors of the transistors Q5 and Q6, a resistor R8 in which one end is connected to a emitter of the transistor Q8 and the other end is connected to a collector of the transistor Q10, a resistor R9 in which one end is connected to a emitter of the transistor Q9 and the other end is connected to the collector of the transistor Q10, and a resistor R10 in which one end is connected to a emitter of the transistor Q10 and the other end is connected to ground.

Although the circuit having the differential configuration is shown in the example in FIG. 5, a single-phase input single-phase output type mixer and a single-phase input single-phase output type filter may be provided instead of the amplifier circuit 3 in the single-phase configuration as shown in FIG. 1.

### Fourth Example

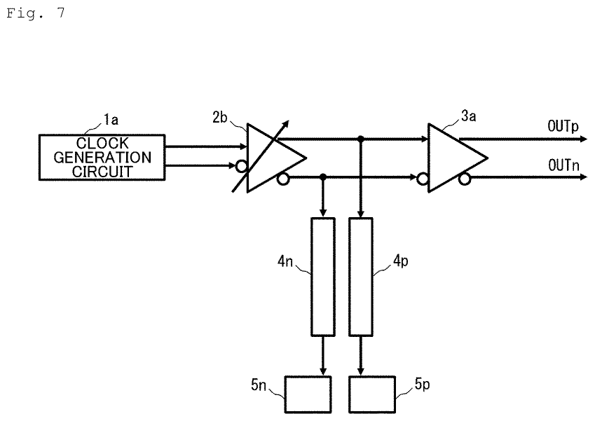

FIG. 7 is a block diagram showing a configuration of a phase adjustment circuit according to a fourth example of the present invention. The phase adjustment circuit of the present example includes a clock generation circuit 1a, a differential input differential output type variable gain amplifier circuit 2b in which a non-inverting input terminal is connected to a non-inverting output terminal of the clock generation circuit 1a and an inverting input terminal is connected to an inverting output terminal of the clock generation circuit 1a, a differential input differential output type amplifier circuit 3a in which a non-inverting input terminal is connected to a non-inverting output terminal of the variable gain amplifier circuit 2b and an inverting input terminal is connected to an inverting output terminal of the variable gain amplifier circuit 2b, transmission lines 4p and 4n, and load circuits 5p and 5n.

In the present example, the variable gain amplifier circuit 2b is provided instead of the amplifier circuit 2a of the second example in order to adjust the amplitude of the differential signals OUTp and OUTn output from the amplifier circuit 3a. Although the configuration of the variable gain amplifier circuit 2b is not limited, the Gilbert cell circuit shown in FIG. 6 may be used, for example.

When the Gilbert cell circuit is used as the variable gain amplifier circuit 2b, a gain control signal on the positive phase side is input instead of IN6p, a gain control signal on the negative phase side is input instead of IN6n, a clock signal on the positive phase side output from the clock generation circuit 1a is input instead of IN7p, and a clock signal on the negative phase side output from the clock generation circuit 1a is input instead of IN7n, in FIG. 6. The gain of the variable gain amplifier circuit 2b can be controlled by a voltage difference between the gain control signal on the positive phase side and the gain control signal on the negative phase side.

### Fifth Example

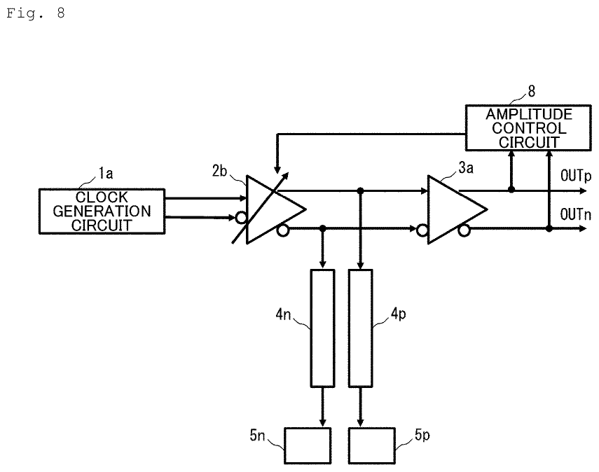

FIG. 8 is a block diagram showing a configuration of a phase adjustment circuit according to a fifth example of the present invention. The phase adjustment circuit of the present example includes a clock generation circuit 1a, a variable gain amplifier circuit 2b, an amplifier circuit 3a, transmission lines 4p and 4n, load circuits 5p and 5n, and an amplitude control circuit 8.

The amplitude control circuit 8 outputs a gain control signal to the variable gain amplifier circuit 2b so that the amplitudes of the output signals OUTp and OUTn of the amplifier circuit 3a become constant.

By doing this, the amplitude of the output signals OUTp and OUTn is made constant by detecting the amplitude of the output signals OUTp and OUTn and performing feedback control for adjusting the gain of the variable gain amplifier circuit 2b.

### Sixth Example

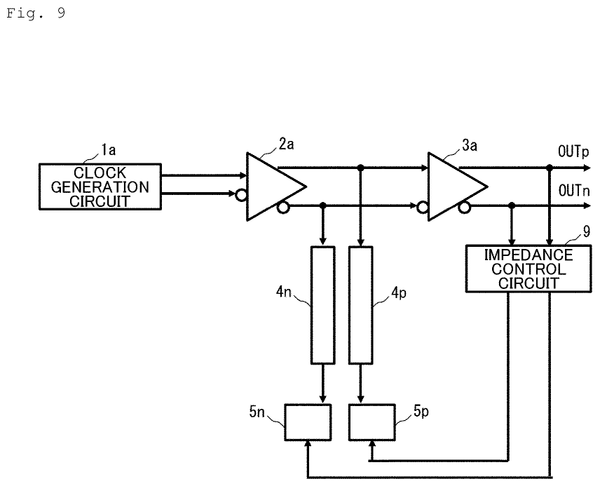

FIG. 9 is a block diagram showing a configuration of a phase adjustment circuit according to a sixth example of the present invention. The phase adjustment circuit of the present example includes a clock generation circuit 1a, amplifier circuits 2a and 3a, transmission lines 4p and 4n, load circuits 5p and 5n, and an impedance control circuit 9.

In the transmission lines 4p and 4n of the differential configuration, the quality of differential signals becomes a problem. In the present example, the impedance control circuit 9 is used in order to maintain the signal quality of differential signals. The impedance control circuit 9 evaluates the signal quality of the differential signals OUTp and OUTn output from the amplifier circuit 3a, and individually controls the impedance of each of the load circuits 5p and 5n on the basis of an evaluation result.

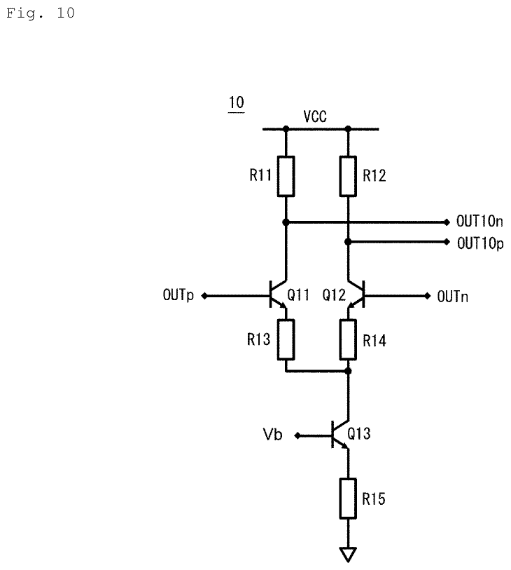

The signal quality can be evaluated by paying attention to the fact that the sum of the output signal OUTp on the positive phase side and the output signal OUTn on the negative phase side is 0. FIG. 10 is a circuit diagram showing a configuration of a signal quality evaluation circuit 10 in the impedance control circuit 9. The signal quality evaluation circuit 10 is configured by an NPN bipolar transistor Q11 in which the output signal OUTp on the positive phase side output from the amplifier circuit 3a is input to a base and the output signal OUT10n on the negative phase side is output from a collector, an NPN bipolar transistor Q12 in which the output signal OUTn on the negative phase side output from the amplifier circuit 3a is input to a base and an output signal OUT10p on the positive phase side is output from a collector, an NPN bipolar transistor Q13 in which the bias voltage Vb is applied to a base, a resistor R11 in which one end is connected to the power supply voltage VCC and the other end is connected to the collector of the transistor Q11, a resistor R12 in which one end is connected to the power supply voltage VCC and the other end is connected to the collector of the transistor Q12, a resistor R13 in which one end is connected to an emitter of the transistor Q11 and the other end is connected to a collector of the transistor Q13, a resistor R14 in which one end is connected to an emitter of the transistor Q12 and the other end is connected to the collector of the transistor Q13, and a resistor R15 in which one end is connected to an emitter of the transistor Q13 and the other end is connected to ground.

When the sum of the differential signals OUTp and OUTn is 0, the difference between the output signals OUT10p and OUT10n of the signal quality evaluation circuit 10 becomes 0. The impedance of the load circuits 5p and 5n is controlled so that the sum of the differential signals OUTp and OUTn becomes 0 (so that the difference between the output signals OUT10p and OUT10n becomes 0), and the quality of the differential signals OUTp and OUTn can be improved.

Since the sum of the differential signals OUTp and OUTn changes depending on time, a processor or the like for performing digital signal processing is provided in the post-stage of the signal quality evaluation circuit 10 in the impedance control circuit 9, the impedance of the load circuits 5p and 5n may be controlled so that the time average of the sum of the differential signals OUTp and OUTn becomes 0 on the basis of the output signals OUT10p and OUT10n of the signal quality evaluation circuit 10.

The signal quality evaluation circuit 10 is not limited to the configuration shown in FIG. 10, but may be realized by a passive multiplexing circuit.

Note that, in the third and sixth examples, the variable gain amplifier circuit 2b may be provided instead of the amplifier circuit 2a. In addition, in the fourth to sixth examples, the mixer 6 and the filter 7 described in the third example may be provided instead of the amplifier circuit 3a.

### Seventh Example

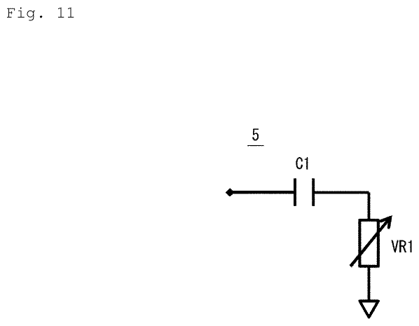

As the load circuits 5, 5p, and 5n in the first to sixth examples, a circuit, as shown in FIG. 11, including a capacitor and a variable resistor for cutting off a DC component can be used. One end of the capacitor C1 is connected to the termination of the transmission lines 4, 4p, and 4n, and the other end of the capacitor C1 is connected to one end of the variable resistor VR1. The other end of the variable resistor VR1 is connected to ground.

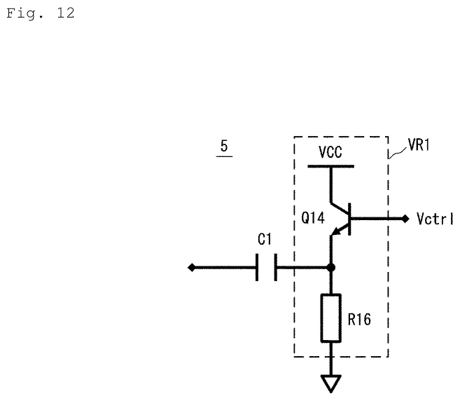

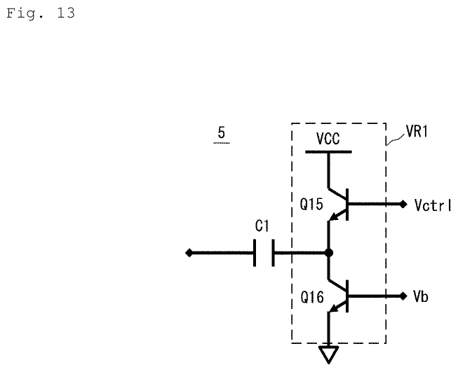

In an actual circuit, the configurations shown in FIG. 12 and FIG. 13 can be adopted as the variable resistor VR1. In the configuration shown in FIG. 12, the variable resistor VR1 is configured by an NPN bipolar transistor Q14 in which a control voltage Vctrl is input to a base, a collector is connected to the power supply voltage VCC, and an emitter is connected to the other end of the capacitor C1, and a resistor R16 in which one end is connected to the emitter of the transistor Q14 and the other end is connected to ground.

In the configuration shown in FIG. 13, the variable resistor VR1 is configured by an NPN bipolar transistor Q15 in which a control voltage Vctrl is input to a base, a collector is connected to the power supply voltage VCC, and an emitter is connected to the other end of the capacitor C1, and an NPN bipolar transistor Q16 in which the bias voltage Vb is applied to a base, a collector is connected to the emitter of the transistor Q15, and an emitter is connected to ground.

In either of the configurations shown in FIG. 12 and FIG. 13, the impedance of the load circuit 5 can be changed by changing the control voltage Vctrl. In the examples shown in FIG. 12 and FIG. 13, when the control voltage Vctrl is increased, the impedance of the load circuit 5 is increased, and when the control voltage Vctrl is decreased, the impedance of the load circuit 5 is decreased.

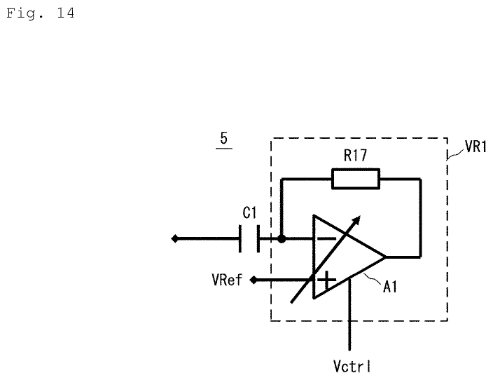

In addition, as shown in FIG. 14, the load circuit 5 may be realized by a feedback configuration using the variable gain amplifier circuit. In the configuration in FIG. 14, a variable resistor VR1 is configured by a variable gain amplifier circuit A1 in which a reference voltage VRef is input to a non-inverting input terminal and an inverting input terminal is connected to the other end of the capacitor C1, and a resistor R17 in which one end is connected to an output terminal of the variable gain amplifier circuit A1 and the other end is connected to an inverting input terminal of the variable gain amplifier circuit A1. In the configuration in FIG. 14, when the gain of the variable gain amplifier circuit A1 is increased, the impedance of the load circuit 5 is decreased, and when the gain of the variable gain amplifier circuit A1 is decreased, the impedance of the load circuit 5 is increased.

The impedance of the load circuit 5 can be changed by changing the gain of the variable gain amplifier circuit A1 by the control voltage Vctrl. The Gilbert cell circuit can be used as the variable gain amplifier circuit A1 similarly to the above.

In the examples shown in FIG. 11 to FIG. 14, the capacitor C1 is inserted due to the balance of bias points, but the termination of the transmission lines 4, 4p, and 4n and the variable resistor VR1 may be directly connected without inserting the capacitor C1 depending on design.

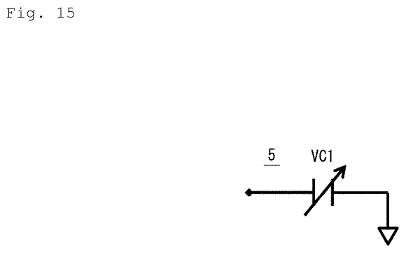

As the load circuits 5, 5p and 5n in the first to sixth examples, a variable capacitor VC1 can be used, as shown in FIG. 15. One end of the variable capacitor VC1 is connected to the termination of the transmission lines 4, 4p, and 4n, and the other end of the variable capacitor VC1 is connected to ground.

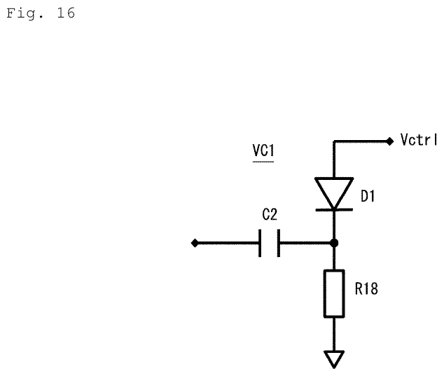

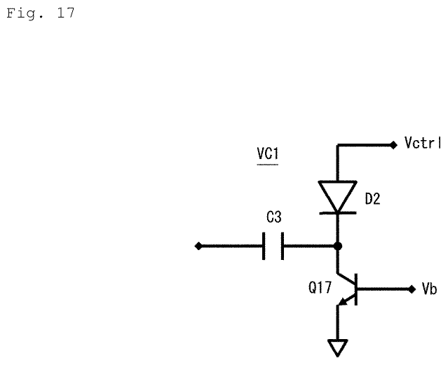

In an actual circuit, the configurations shown in FIG. 16 and FIG. 17 can be adopted as the variable capacitor VC1. In the configuration shown in FIG. 16, the variable capacitor VC1 is configured by a capacitor C2 in which one end is connected to the termination of the transmission lines 4, 4p, and 4n, a diode D1 in which the control voltage Vctrl is input to an anode and a cathode is connected to the other end of the capacitor C2, and a resistor R18 in which one end is connected to the cathode of the diode D1 and the other end is connected to ground.

In the configuration shown in FIG. 17, the variable capacitor VC1 is configured by a capacitor C3 in which one end is connected to the termination of the transmission lines 4, 4p, and 4n, a diode D2 in which the control voltage Vctrl is input to an anode and a cathode is connected to the other end of the capacitor C3, and an NPN bipolar transistor Q17 in which the bias voltage Vb is applied to a base, a collector is connected to the cathode of the diode D2, and an emitter is connected to ground.

In either of the configurations shown in FIG. 16 and FIG. 17, the impedance of the load circuit 5 can be changed by changing the control voltage Vctrl. In the examples shown in FIG. 16 and FIG. 17, when the control voltage Vctrl is increased, the impedance of the load circuit 5 is increased, and when the control voltage Vctrl is decreased, the impedance of the load circuit 5 is decreased.

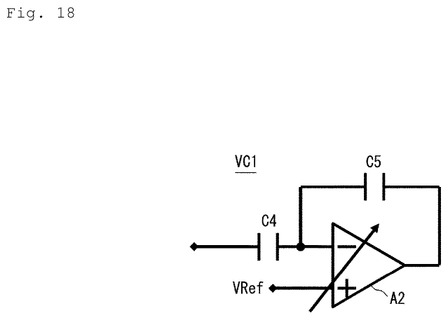

In addition, as shown in FIG. 18, the variable capacitor VC1 may be realized by a feedback configuration using the variable gain amplifier circuit. In the configuration shown in FIG. 18, the variable capacitor VC1 is configured by a capacitor C4 in which one end is connected to the termination of the transmission lines 4, 4p, and 4n, a variable gain amplifier circuit A2 in which the reference voltage VRef is input to a non-inverting input terminal and an inverting input terminal is connected to the other end of the capacitor C4, and a capacitor C5 in which one end is connected to an output terminal of the variable gain amplifier circuit A2 and the other end is connected to the inverting input terminal of the variable gain amplifier circuit A2. In the configuration in FIG. 18, when the gain of the variable gain amplifier circuit A2 is increased, the impedance of the load circuit 5 is decreased, and when the gain of the variable gain amplifier circuit A2 is decreased, the impedance of the load circuit 5 is increased.

The impedance of the load circuit 5 can be changed by changing the gain of the variable gain amplifier circuit A2 by the control voltage Vctrl. The Gilbert cell circuit can be used as the variable gain amplifier circuit A2 similarly to the above.

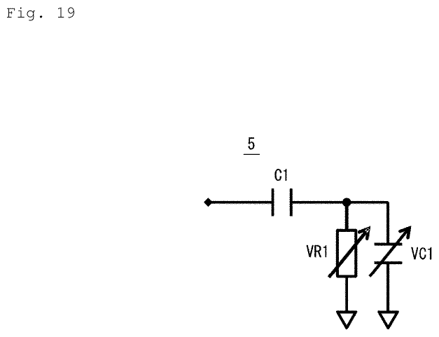

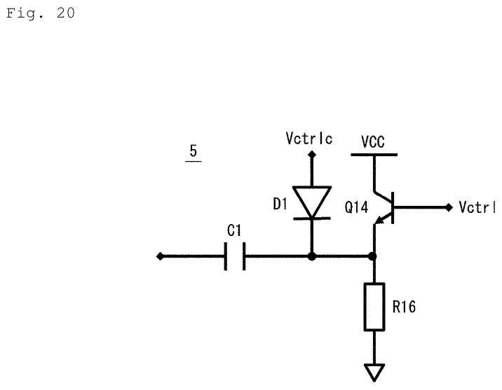

As the load circuits 5, 5p and 5n in the first to sixth examples, a circuit in which a variable resistor VR1 and a variable capacitor VC1 are combined can be used, as shown in FIG. 19. In an actual circuit, the configurations shown in FIG. 20 to FIG. 22 can be adopted as the load circuits 5, 5p, and 5n.

In the configuration shown in FIG. 20, the load circuit 5 is configured by a capacitor C1 in which one end is connected to the termination of the transmission lines 4, 4p, and 4n, an NPN bipolar transistor Q14 in which the control voltage Vctrl is input to a base, a collector is connected to the power supply voltage VCC, and an emitter is connected to the other end of the capacitor C1, a resistor R16 in which one end is connected to the emitter of the transistor Q14 and the other end is connected to ground, and a diode D1 in which the control voltage Vctrlc is input to an anode, and a cathode is connected to the other end of the capacitor C1.

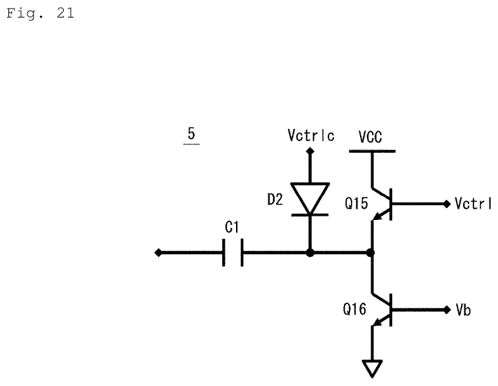

In the configuration shown in FIG. 21, the load circuit 5 is configured by a capacitor C1 in which one end is connected to the termination of the transmission lines 4, 4p, and 4n, an NPN bipolar transistor Q15 in which the control voltage Vctrl is input to a base, a collector is connected to the power supply voltage VCC, and an emitter is connected to the other end of the capacitor C1, an NPN bipolar transistor Q16 in which the bias voltage Vb is applied to a base, a collector is connected to the emitter of the transistor Q15, and a emitter is connected to ground, and a diode D2 in which the control voltage Vctrlc is input to an anode, and a cathode is connected to the other end of the capacitor C1.

In the examples of FIG. 20 and FIG. 21, when the control voltages Vctrl and Vctrlc are increased, the impedance of the load circuit 5 is increased, when Vctrl and Vctrlc are decreased, the impedance of the load circuit 5 is decreased.

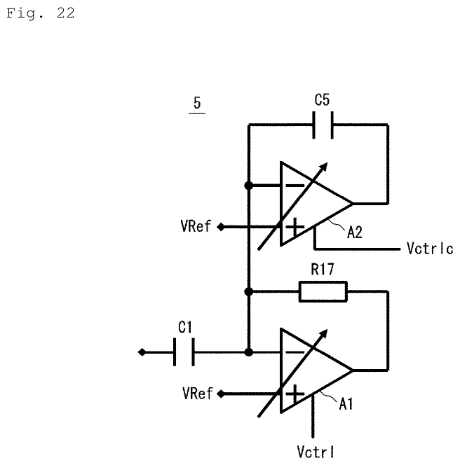

In the configuration shown in FIG. 22, the load circuit 5 is configured by a capacitor C1 in which one end is connected to the termination of the transmission lines 4, 4p, and 4n, a variable gain amplifier circuit A1 in which the reference voltage VRef is input to a non-inverting input terminal and an inverting input terminal is connected to the other end of the capacitor C1, a resistor R17 in which one end is connected to an output terminal of the variable gain amplifier circuit A1 and the other end is connected to an inverting input terminal of the variable gain amplifier circuit A1, a variable gain amplifier circuit A2 in which the reference voltage VRef is input to a non-inverting input terminal and an inverting input terminal is connected to the other end of the capacitor C1, and a capacitor C5 in which one end is connected to an output terminal of the variable gain amplifier circuit A2 and the other end is connected to an inverting input terminal of the variable gain amplifier circuit A2.

In the configuration shown in FIG. 22, when the gains of the variable gain amplifier circuits A1 and A2 are increased, the impedance of the load circuit 5 is decreased, and when the gains of the variable gain amplifier circuits A1 and A2 are decreased, the impedance of the load circuit 5 is increased. The impedance of the load circuit 5 can be changed by changing the gains of the variable gain amplifier circuits A1 and A2 by the control voltages Vctrl and Vctrlc.

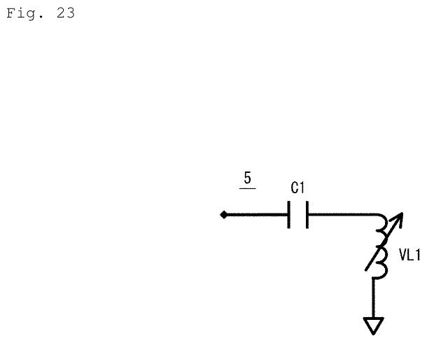

As the load circuits 5, 5p and 5n in the first to sixth examples, a variable inductor VL1 can be used, as shown in FIG. 23. One end of the capacitor C1 is connected to the termination of the transmission lines 4, 4p, and 4n, and the other end of the capacitor C1 is connected to one end of the variable inductor VL1. The other end of the variable inductor VL1 is connected to ground.

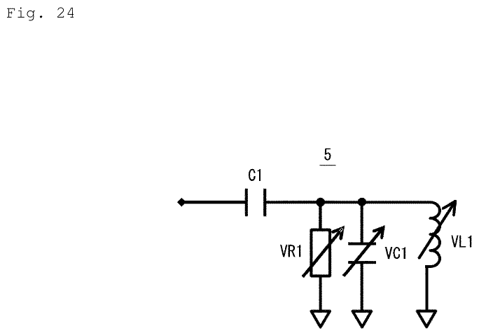

As the load circuits 5, 5p, and 5n in the first to sixth examples, a circuit in which a variable resistor VR1, a variable capacitor VC1, and a variable inductor VL1 are combined can be used, as shown in FIG. 24. In addition, the variable resistor VR1 and the variable inductor VL1 may be combined, or the variable capacitor VC1 and the variable inductor VL1 may be combined.

In FIG. 11 to FIG. 24, the configuration of the load circuit 5 is described as an example, but the configuration of the load circuits 5p and 5n is the same as that of the load circuit 5.

As described in the sixth example, when the load circuits 5p and 5n and the impedance control circuit 9 are combined and the sum of the differential signals OUTp and OUTn is positive, the impedance of the load circuit 5n is increased to decrease the impedance of the load circuit 5p.
In addition, when the sum of the differential signals OUTp and OUTn is negative, the impedance of the load circuit 5p is increased to decrease the impedance of the load circuit 5n.

### Eighth Example

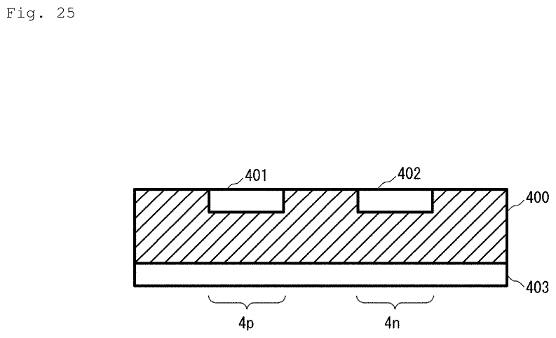

Next, an eighth example of the present invention will be described. The present example shows a specific example of the transmission lines 4, 4p, and 4n of the first to seventh examples. Cross-sectional views of the transmission lines 4p and 4n are shown in FIG. 25 to FIG. 27. The example in FIG. 25 shows an example of a micro-strip line. The transmission line 4p is configured by a dielectric 400, a signal line 401 including a conductor formed on a front face of the dielectric 400, and a ground plane 403 made of a conductor formed on a back face of the dielectric 400. The transmission line 4n is configured by the dielectric 400, a signal line 402 made of the conductor formed on the front surface of the dielectric 400, and the ground plane 403.

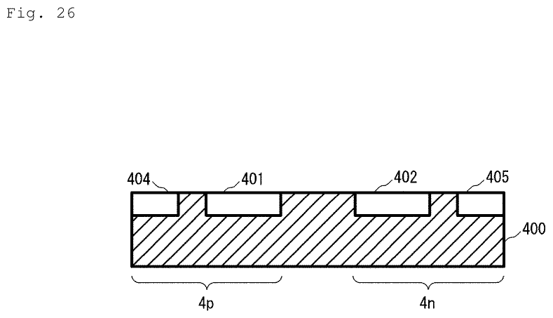

The example in FIG. 26 shows an example of a coplanar line. The transmission line 4p includes a dielectric 400, a signal line 401, and a ground plane 404 made of a conductor formed on a front surface of the dielectric 400 on an opposite side of a signal line 402 with a signal line 401 in between. The transmission line 4n includes the dielectric 400, the signal line 402, and the ground plane 405 made of the conductor formed on the front surface of the dielectric 400 on the opposite side of the signal line 401 with the signal line 402 in between.

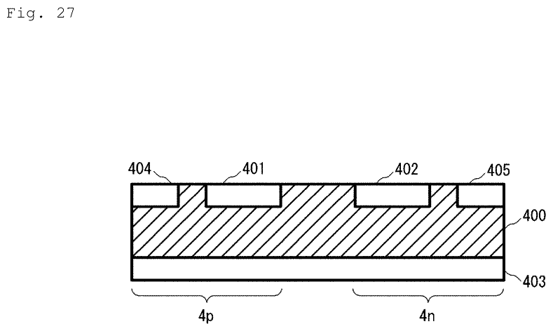

In the present invention, in order to reduce a mounting area, a composite type structure in which the coplanar line and the micro-strip line are particularly combined may be adopted. The example in FIG. 27 shows an example of a composite type coplanar line with a back face ground. The transmission line 4p is configured by the dielectric 400, the signal line 401, and the ground planes 403 and 404. The transmission line 4n is configured by the dielectric 400, the signal line 402, and the ground planes 403 and 405.

In FIG. 25 to FIG. 27, the configuration of the transmission lines 4p and 4n is described as an example, but in the case of the transmission line 4, only one of the signal lines 401 and 402 may be provided.

The structure of the transmission lines 4, 4p, and 4n is not limited to the cross-sectional structures shown in FIG. 25 to FIG. 27, but other structures may be adopted as long as the characteristic impedance can be defined.

Although the example in which the bipolar transistors are used as the transistors Q1 to Q17 is shown in FIG. 4, FIG. 6, FIG. 10, FIG. 12, FIG. 13, FIG. 17, FIG. 20, and FIG. 21, a MOS transistor may be used. When the MOS transistor is used, in the above-described description, the base may be replaced with a gate, the collector may be replaced with a drain, and the emitter may be replaced with a source.

Some or all of the above-described examples are also described in the following supplements, but are not limited to the following.

(Supplement 1) A phase adjustment circuit of the present invention includes a clock generation circuit configured to generate a sine wave shaped clock signal, an amplifier circuit configured to amplify the clock signal output from the clock generation circuit, a transmission line in which an input end is connected to an output terminal of the amplifier circuit, a load circuit which is connected to a termination of the transmission line and whose impedance can be adjusted from the outside, and an output circuit in which a signal obtained by adding an output signal of the amplifier circuit and a return signal from the transmission line at the output terminal of the amplifier circuit is input.

(Supplement 2) In the phase adjustment circuit described in the supplement 1, the load circuit includes a variable resistor whose impedance can be adjusted from the outside.

(Supplement 3) In the phase adjustment circuit described in the supplement 1, the load circuit includes a variable capacitor whose impedance can be adjusted from the outside.

(Supplement 4) In the phase adjustment circuit described in the supplement 1, the load circuit includes a variable inductor whose impedance can be adjusted from the outside.

(Supplement 5) In the phase adjustment circuit described in the supplement 1, the load circuit includes a combination of at least two of the variable resistor, the variable capacitor, and the variable inductor whose impedance can be adjusted from the outside.

(Supplement 6) In the phase adjustment circuit described in the supplement 1, the clock generation circuit generates a sine wave shaped differential clock signal, the amplifier circuit is a differential input differential output type circuit for amplifying the differential clock signal, the transmission line includes a first transmission line in which an input end is connected to a non-inverting output terminal of the amplifier circuit and a second transmission line in which an input end is connected to an inverting output terminal of the amplifier circuit, the load circuit includes a first load circuit which is connected the termination of the first transmission line and whose impedance can be adjusted from the outside and a second load circuit which is connected the termination of the second transmission line and whose impedance can be adjusted from the outside, the output circuit is a differential input differential output type circuit in which a signal obtained by adding an output signal on a positive phase side of the amplifier circuit and a return signal from the first transmission line at a non-inverting output terminal of the amplifier circuit, and a signal obtained by adding an output signal on the negative phase side of the amplifier circuit and a return signal from the second transmission line at an inverting output terminal of the amplifier circuit are input, and an impedance control circuit configured to control the impedance of the first and second load circuits so that a sum of differential signals output from the output circuit becomes 0 is further included.

(Supplement 7) In the phase adjustment circuit described in the supplement 1, the output circuit is an amplifier circuit configured to amplify the signal added at the output terminal of the amplifier circuit.

(Supplement 8) In the phase adjustment circuit described in the supplement 1, the output circuit is configured by a mixer configured to mix a signal added at the output terminal of the amplifier circuit with a carrier wave signal input from the outside and a filter configured to perform wave-filtering to an output signal of the mixer and pass a signal of a desired frequency.

### INDUSTRIAL APPLICABILITY

The present invention can be applied to a technique of adjusting a phase of a sine wave.

### REFERENCE SIGNS LIST

1, 1a Clock generation circuit
2, 2a, 3, 3a Amplifier circuit
2b, A1, A2 Variable gain amplifier circuit
4, 4p, 4n Transmission line
5, 5p, 5n Load circuit
6 Mixer
7 Filter
8 Amplitude control circuit
9 Impedance control circuit
10 Signal quality evaluation circuit
400 Dielectric
401, 402 Signal line
403 to 405 Ground plane
Q1 to Q17 NPN transistor
D1, D2 Diode
R1 to R18 Resistor
C1 to C5 Capacitor
VR1 Variable resistor
VC1 Variable capacitor
VL1 Variable inductor

1-8. (canceled)

9. A phase adjustment circuit comprising:
a clock generation circuit configured to generate a sine wave shaped clock signal;
an amplifier circuit configured to amplify the clock signal output from the clock generation circuit;
a transmission line including an input end connected to an output terminal of the amplifier circuit;
a load circuit connected to a termination of the transmission line and having adjustable impedance; and
an output circuit configured to receive a signal obtained by adding an output signal of the amplifier circuit and a return signal from the transmission line at the output terminal of the amplifier circuit and output an output signal.

10. The phase adjustment circuit according to claim 9, wherein
the load circuit includes a variable resistor having adjustable impedance.

11. The phase adjustment circuit according to claim 9, wherein
the load circuit includes a variable capacitor having adjustable impedance.

12. The phase adjustment circuit according to claim 9, wherein
the load circuit includes a variable inductor having adjustable impedance.

13. The phase adjustment circuit according to claim 9, wherein
the load circuit includes a combination of at least two of a variable resistor, a variable capacitor, and a variable inductor, respective impedance being adjustable.

14. The phase adjustment circuit according to claim 9, further comprising
an impedance control circuit configured to control the impedance of the load circuit;
wherein
the clock generation circuit generates a sine wave shaped differential clock signal,
the amplifier circuit is a differential input differential output type circuit for amplifying the differential clock signal,
the transmission line includes
a first transmission line including an input end connected to a non-inverting output terminal of the amplifier circuit, and
a second transmission line including an input end connected to an inverting output terminal of the amplifier circuit,
the load circuit includes
a first load circuit connected to the termination of the first transmission line, the first load circuit having adjustable impedance, and
a second load circuit connected to the termination of the second transmission line, the second load circuit having adjustable impedance,
the output circuit is a differential input differential output type circuit configured to receive a first signal obtained by adding an output signal on a positive phase side of the amplifier circuit and a return signal from the first transmission line at a non-inverting output terminal of the amplifier circuit, and a second signal obtained by adding an output signal on the negative phase side of the amplifier circuit and a return signal from the second transmission line at an inverting output terminal of the amplifier circuit, and
the impedance control circuit controls the impedance of the first and second load circuits so that a sum of differential signals output from the output circuit becomes 0.

15. The phase adjustment circuit according to claim 9, wherein
the output circuit is an amplifier circuit configured to amplify a signal added at the output terminal of the amplifier circuit.

16. The phase adjustment circuit according to claim 9, wherein
the output circuit includes
a mixer configured to mix a signal added at the output terminal of the amplifier circuit with a carrier wave signal input from the outside, and
a filter configured to perform wave-filtering to an output signal of the mixer and pass a signal of a desired frequency.
